(19) United States
(12) Patent Application Publication
(10) Pub. No.: US 2023/0197462 A1
(43) Pub. Date: Jun. 22, 2023

(54) METHOD FOR INHIBITING FORMABLE MATERIAL EVAPORATION, SYSTEM FOR INHIBITING EVAPORATION, AND METHOD OF MAKING AN ARTICLE

(71) Applicant: CANON KABUSHIKI KAISHA, Tokyo (JP)

(72) Inventors: Steven C. Shackleton, Austin, TX (US); Edward Brian Fletcher, Austin, TX (US); Zhengmao Ye, Austin, TX (US); Craig William Cone, Austin, TX (US); Hiroyuki Kondo, Utsunomiya (JP)

(21) Appl. No.: 17/557,940

(22) Filed: Dec. 21, 2021

(51) Int. Cl. H01L 21/3105

(52) U.S. Cl. CPC H01L 21/31051

(57) ABSTRACT

A method of inhibiting evaporation of a formable material on a substrate, the method comprising holding the substrate with a substrate chuck, the substrate chuck being positioned within a central opening of a frame such that the frame surrounds at least a portion of the substrate chuck, supplying the formable material or a volatile material different from the formable material to a portion of the frame surrounding the substrate chuck, and dispensing the formable material on the substrate.

### BACKGROUND

### Field Of Art

The present disclosure relates to substrate processing, and more particularly, to planarization or imprinting of surfaces in semiconductor fabrication.

### Description of the Related Art

Planarization and imprinting techniques are useful in fabricating semiconductor devices. For example, the process for creating a semiconductor device includes repeatedly adding and removing material to and from a substrate. This process can produce a layered substrate with an irregular height variation (i.e., topography), and as more layers are added, the substrate height variation can increase. The height variation has a negative impact on the ability to add further layers to the layered substrate. Separately, semiconductor substrates (e.g., silicon wafers) themselves are not always perfectly flat and may include an initial surface height variation (i.e., topography). One method of addressing this issue is to planarize the substrate between layering steps. Various lithographic patterning methods benefit from patterning on a planar surface. In ArFi laser-based lithography, planarization reduces the impact of depth of focus (DOF) limitations, and improves critical dimension (CD), and critical dimension uniformity. In extreme ultraviolet lithography (EUV), planarization improves feature placement and reduces the impact of DOF limitations. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is polymerized on the substrate, and the superstrate removed. Improvements in planarization techniques, including IAP techniques, are desired for improving, e.g., whole wafer processing and semiconductor device fabrication.

A step in a planarization/imprint method includes dispensing a formable material onto a substrate. After dispensing the formable material, the formable material may evaporate during subsequent processing. In particular, the evaporation of the formable material may occur at the edges of the substrate. This evaporation leads to an undesirable amount deviation from a target residual layer thickness (RLT). Thus, there is a need for a planarization/imprint system and method that inhibits evaporation of formable material on the substrate during a planarizing/imprinting process.

### SUMMARY

In an embodiment, a method of inhibiting evaporation of a formable material on a substrate comprises holding the substrate with a substrate chuck, the substrate chuck being positioned within a central opening of a frame such that the frame surrounds at least a portion of the substrate chuck, supplying the formable material or a volatile material different from the formable material to a portion of the frame surrounding the substrate chuck, and dispensing the formable material on the substrate.

In an embodiment, a system for inhibiting evaporation of a formable material on a substrate comprises a frame defining a central opening, a substrate chuck configured to hold the substrate, the substrate chuck being positioned within the central opening of the frame such that the frame surrounds at least a portion of the substrate chuck, and a material supply system configured to supply the formable material or a volatile material different from the formable material to a portion of the frame surrounding the substrate chuck.

In an embodiment, a method of manufacturing an article comprises holding a substrate with a substrate chuck, the substrate chuck being positioned within a central opening of a frame such that the frame surrounds at least a portion of the substrate chuck, supplying a formable material or a volatile material different from the formable material to a portion of the frame surrounding the substrate chuck, dispensing formable material onto the substrate, forming a pattern or a layer of the dispensed formable material on the substrate, curing the formed pattern or layer, and processing the cured pattern or layer to make the article.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure and are therefore not to be considered limiting of its scope, for the disclosure may admit to other equally effective embodiments.

FIG. 1 is a schematic diagram illustrating an example planarization system in accordance with an aspect of the present disclosure.

FIG. 2A shows a schematic plan view of a frame used in the example system of FIG. 1 in accordance with an aspect of the present disclosure.

FIG. 2B shows a schematic cross section of a substrate and a substrate chuck when placed within a central opening of the frame of FIG. 2A in accordance with an aspect of the present disclosure.

FIG. 2C shows an exploded view of FIG. 2B in accordance with an aspect of the present disclosure.

FIG. 3A shows a flow chart of an example planarization method in accordance with aspect of the present disclosure.

FIG. 3B shows a flow chart of an example evaporation inhibiting method in accordance with an aspect of the present disclosure.

FIG. 4A shows a schematic cross section view of the planarization process when a formable material or a volatile material different from the formable material is supplied to a portion of a frame surrounding a substrate chuck, in accordance with a first aspect of the present disclosure.

FIG. 4B shows a schematic plan view of the planarization process when the formable material or the volatile material different from the formable material is supplied to the portion of the frame surrounding the substrate chuck, in accordance with the first aspect of the present disclosure.

FIG. 5A shows a schematic cross section view of the planarization process when the formable material or the volatile material different from the formable material is supplied to the portion of the frame surrounding the substrate chuck, in accordance with a second aspect of the present disclosure.

FIG. 5B shows a schematic bottom view of a nozzle system used to dispense the formable material or the volatile material different from the formable material to the portion of the frame surrounding the substrate chuck, in accordance with the second aspect of the present disclosure.

FIG. 5C shows a schematic plan view of the planarization process when the formable material or the volatile material different from the formable material is supplied to the portion of the frame surrounding the substrate chuck, in accordance with the second aspect of the present disclosure.

FIG. 6A shows a schematic cross section view of the planarization process when the formable material or the volatile material different from the formable material is supplied to the portion of the frame surrounding the substrate chuck, in accordance with a third aspect of the present disclosure.

FIG. 6B shows a schematic cross section view of a portion of FIG. 6A in accordance with the third aspect of the present disclosure.

FIG. 6C shows a schematic plan view of the planarization process just prior to the formable material or the volatile material different from the formable material being supplied to the portion of the frame surrounding the substrate chuck, in accordance with the third aspect of the present disclosure.

FIG. 6D shows a schematic plan view of the planarization process when the formable material or the volatile material different from the formable material is supplied to the portion of the frame surrounding the substrate chuck, in accordance with the third aspect of the present disclosure.

FIG. 7A shows a schematic cross section view of the planarization process when the formable material or the volatile material different from the formable material is supplied to the portion of the frame surrounding the substrate chuck, in accordance with a fourth aspect of the present disclosure.

FIG. 7B shows a schematic cross section view of a portion of FIG. 7A, in accordance with the fourth aspect of the present disclosure.

FIG. 7C shows a schematic plan view of the planarization process when the formable material or the volatile material different from the formable material is supplied to the portion of the frame surrounding the substrate chuck, in accordance with the fourth aspect of the present disclosure.

FIG. 8A shows a schematic cross section view of the planarization process when the formable material or the volatile material different from the formable material is supplied to the portion of the frame surrounding the substrate chuck, in accordance with a fifth aspect of the present disclosure.

FIG. 8B shows a schematic cross section view of a portion of the planarization process shown in FIG. 7A, in accordance with the fifth aspect of the present disclosure.

FIG. 8C shows a schematic plan view of the planarization process when the formable material or the volatile material different from the formable material is supplied to the portion of the frame surrounding the substrate chuck, in accordance with the fifth aspect of the present disclosure.

FIG. 9A shows a schematic cross section view of the planarization process when the formable material or the volatile material different from the formable material is supplied to the portion of the frame surrounding the substrate chuck, in accordance with a sixth aspect of the present disclosure.

FIG. 9B shows a schematic cross section view of a portion of the planarization process shown in FIG. 8A, in accordance with the sixth aspect of the present disclosure.

FIG. 9C shows a schematic plan view of the planarization process when the formable material or the volatile material different from the formable material is supplied to the portion of the frame surrounding the substrate chuck, in accordance with the sixth aspect of the present disclosure.

FIG. 10A shows a schematic cross section view of the planarization process when the formable material or the volatile material different from the formable material is supplied to the portion of the frame surrounding the substrate chuck, in accordance with a seventh aspect of the present disclosure.

FIG. 1013 shows a schematic cross section view of a portion of the planarization process shown in FIG. 9A, in accordance with the seventh aspect of the present disclosure.

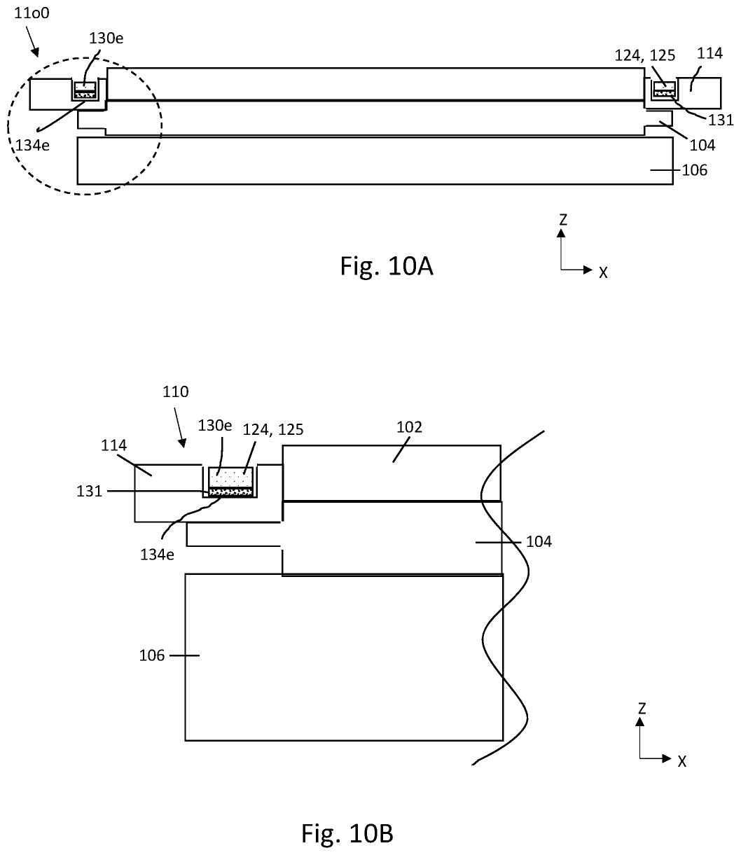

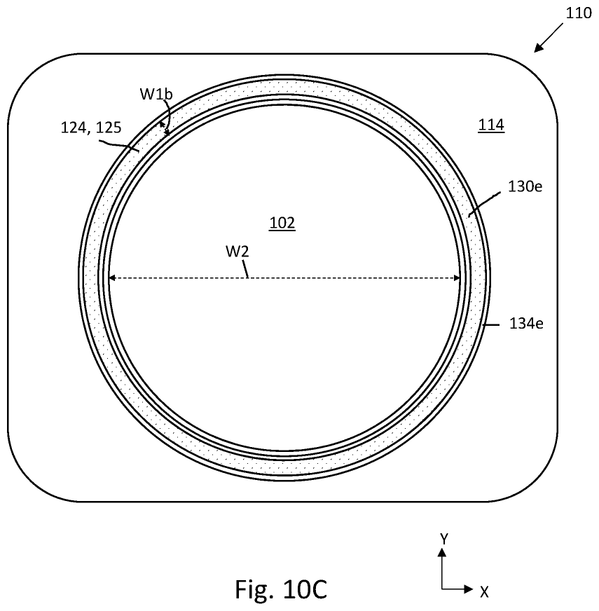

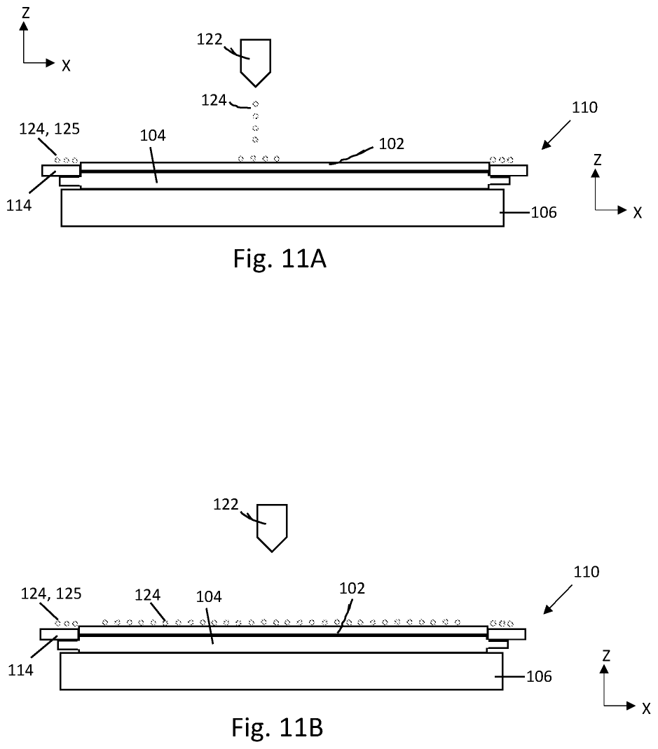

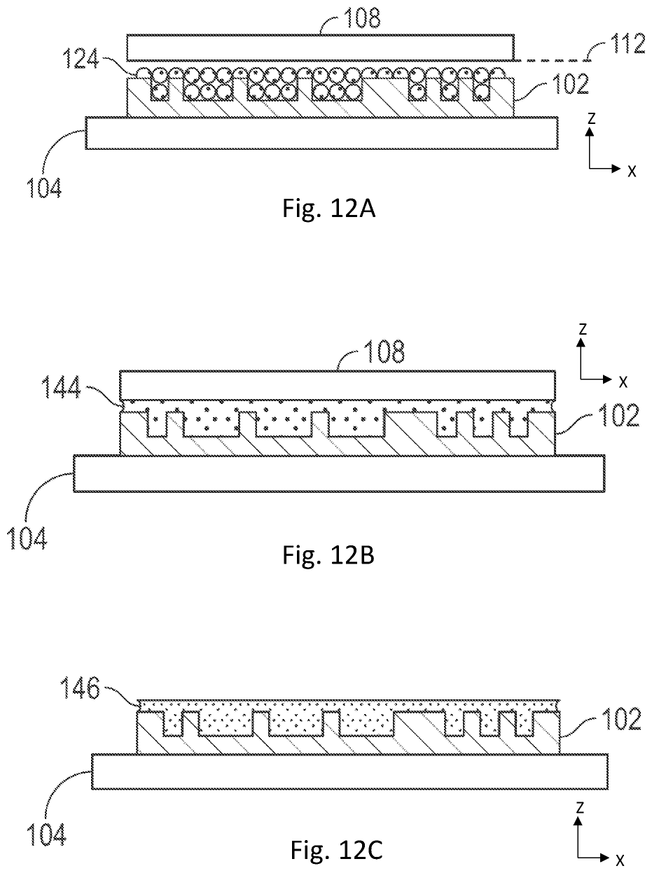

FIG. 10C shows a schematic plan view of the planarization process when the formable material or the volatile material different from the formable material is supplied to the portion of the frame surrounding the substrate chuck, in accordance with the seventh aspect of the present disclosure.

FIG. 11A shows a schematic cross section view of the planarization process as the formable material is supplied to the substrate, in accordance with an aspect of the present disclosure.

FIG. 11B shows a schematic cross section view of the planarization process after the formable material is completely supplied to the substrate, in accordance with an aspect of the present disclosure.

FIGS. 12A to 12C illustrate a schematic cross section of an example planarization process in accordance aspect of the present disclosure.

While the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

### Planarization System

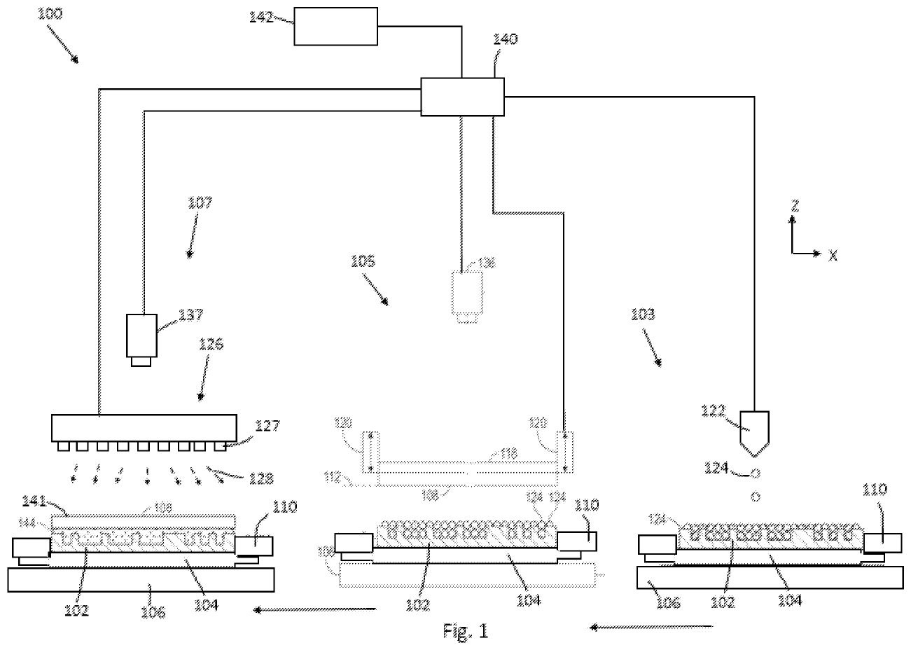

FIG. 1 illustrates an example system for shaping a surface in accordance with an aspect of the present disclosure. The system for shaping a surface may be, for example, a planarization system or an imprint system. The example embodiment described herein and illustrated in FIG. 1 is a planarization system 100. However, the concepts are also applicable to an imprint system. Thus, while the terminology throughout this disclosure is primarily focused on planarization, it should be understood that the disclosure is also applicable to the corresponding terminology of an imprint context.

The shaping system, e.g., the planarization system 100, is used to planarize a film on a substrate 102. In the case of the shaping system being an imprint system, the imprint system is used to form a pattern on the film on the substrate. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be supported by a substrate positioning stage 106. The substrate positioning stage 106 may provide translational and/or rotational motion along one or more of the x-, y-, z-, θ-, Ψ, and φ-axes. The substrate positioning stage 106, the substrate 102, and the substrate chuck 104 may also be positioned on a base (not shown).

As shown in FIG. 1, in an example embodiment, the planarization system 100 may include three separate stations: a dispensing station 103, a shaping station (e.g., a planarizing station 105), and a curing station 107. The three stations may be located at different locations. A positioning system may be included that is capable transferring the substrate 102 to each of the three stations. In some instances, a stage 106 may participate in the movement of the substrate 102. In an example embodiment, the planarizing station 105 is located at a first location, the dispensing station 103 is located at a second location, and the curing station 107 is located at a third location, where each location is different. In these example embodiments the substrate 102 is carried from the dispensing station 103 to the planarizing station 105, and finally to the curing station, using the positioning system.

Each of the stations may include a frame 110 that partially surrounds the outer perimeter of the substrate chuck 104. More particularly, as shown in FIG. 1, each of the dispensing station 103, the planarization station 105, and the curing station 107, may include a separate frame 110, as well as a separate substrate chuck 104 and a separate positioning stage 106. That is, the same reference number is used to designate the frame 110, the substrate chuck 104, and the positioning stage 106 in all of the stations because the structure of the frame 110, substrate chuck 104, and positioning stage 106 is identical at each station. However, it should be understood that each station has its own frame 110, substrate chuck 104, and positioning stage 106.

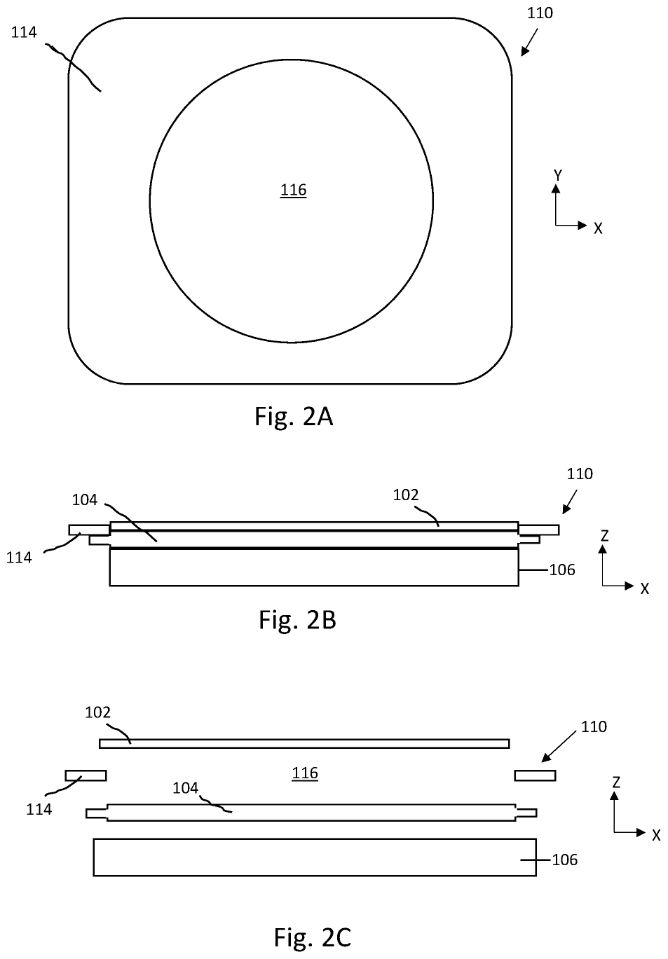

FIG. 2A shows a schematic plan view of the frame 110. As shown in FIG. 2A the frame 110 includes a body 114 defining a central opening 116. In the example aspect shown in FIG. 2A, the central opening 116 is circular and the body 114 is a square with rounded corners. The body 114 may have other shapes such as a rectangle, circle, etc. The central opening 116 surrounds a portion of the substrate chuck 104 and the substrate 102 when the substrate 102 is held by the substrate chuck 104. Thus, the central opening 116 should have a shape that compliments the outer perimeter of the substrate chuck 104 and/or the substrate 102. Because the outer perimeter of the substrate chuck 104 and the substrate 104 are generally circular in shape, the central opening 116 may also be circular.

FIG. 2B shows a schematic cross section of the substrate 102 and the substrate chuck 104 when placed within the central opening 116 of the frame 110. FIG. 2C shows an exploded view of FIG. 2B. As shown in FIGS. 2B and 2C, the size of the central opening 116 of the frame 110 is selected such that the substrate 102 and the substrate chuck 104 fit within the central opening 116. As best seen in FIG. 2B, when the substrate chuck 104 is placed within the central opening 116, the body 114 of the frame 110 partially surrounds an outer edge of the substrate chuck 104. Similarly, as shown in FIG. 2B, when the substrate 102 is held by the substrate chuck 104, the body 114 of the frame 110 partially surrounds an outer edge of the substrate 102. In another aspect, the body 114 of the frame 110 may surround the entirety of the outer edge of the substrate chuck 104 and/or the substrate 102.

The dispensing station 103 may comprise a fluid dispenser 122. The fluid dispenser 122 may be used to deposit droplets of liquid formable material 124 (e.g., a photocurable polymerizable material) onto the substrate 102 with the volume of deposited material varying over the area of the substrate 102 based on at least in part upon its topography profile. The formable material may be a photocurable composition comprising a photoinitiator and monomers. Example monomers which may be in the photocurable composition include: acrylate monomers; vinyl monomers; styrenic monomers; etc. The formable material may have the composition described in U.S. Pat. App. Pub. No. 2020/0339828, which is hereby expressly incorporated by reference herein. As discussed in U.S. Pat. App. Pub. No. 2020/0339828, the formable material may be a photocurable composition comprising a polymerizable material and a photoinitiator, wherein at least 90 wt % of the polymerizable material may comprise acrylate monomers including an aromatic group. The photocurable composition can have a viscosity of not greater than 10, 15, 20, or 30 mPa·s, the total carbon content of the photocurable composition after curing can be at least 73%, and the Ohnishi number may be not greater than 3.0. At least 90 wt % of the polymerizable material can include monomers containing an aromatic group in their chemical structure. Some non-limiting examples of monomers comprising an aromatic group can be: benzyl acrylate (BA), benzyl methacrylate (BMA), 1-naphthyl methacrylate (1-NMA), bisphenol A dimethacrylate (BPADMA), 1-naphthyl acrylate (1-NA), 2-naphthyl acrylate (2-NA), 9,9-bis[4-(2-acryloyloxy ethoxy) phenyl]fluorine (A-BPEF), 9-fluorene methacrylate (9-FMA), 9-fluorene acrylate (9-FA), o-phenylbenzyl acrylate (o-PBA), bisphenol A diacrylate (BPADA), propenoic acid, 1,1′-[1,1′-binaphthalene]-2,2′-diyl ester (BNDA), styrene, divinyl benzene (DVB). Further details of the composition may be found in U.S. Pat. App. Pub. No. 2020/0339828. Some non-limiting examples of suitable monofunctional (meth)acrylates to be included in the polymerizable material are: isobornyl acrylate; 3,3,5-trimethylcyclohexyl acrylate; dicyclopentenyl acrylate; dicyclopentanyl acrylate; dicyclopentenyl oxyethyl acrylate; benzyl acrylate; naphthyl acrylate; 2-phenylethyl acrylate; 2-phenoxyethyl acrylate; phenyl acrylate; (2-ethyl-2-methyl-1,3-dioxolan-4-yl)methyl acrylate; o-phenyl benzyl acrylate; butyl acrylate; ethyl acrylate; methyl acrylate; n-hexyl acrylate; 2-ethyl hexyl acrylate; 4-tert-butylcyclohexyl acrylate; methoxy polyethylene glycol (350) monoacrylate; 2-methoxyethyl acrylate; lauryl acrylate; stearyl acrylate; 9-fluorene acrylate. Some non-limiting examples of suitable diacrylates to be included in the polymerizable material are: ethylene glycol diacrylate; diethylene glycol diacrylate; triethylene glycol diacrylate; tetraethylene glycol diacrylate; 1,2-propanediol diacrylate; dipropylene glycol diacrylate; tripropylene glycol diacrylate; polypropylene glycol diacrylate; 1,3-propanediol diacrylate; 1,4-butanediol diacrylate; 2-butene-1,4-diacrylate; 1,3-butylene glycol diacrylate; 3-methyl-1,3-butanediol diacrylate; 1,5-pentanediol diacrylate; 3-Methyl-1,5-pentanediol diacrylate; neopentyl glycol diacrylate; tricyclodecane dimethanol diacrylate; 1,6-hexanediol diacrylate; 1,9-nonanediol diacrylate; 1,10-decanediol diacrylate; 1,12-dodecanediol diacrylate; cyclohexane dimethanol diacrylate; bisphenol A diacrylate; ethoxylated bisphenol A diacrylate; m-xylylene diacrylate; 9,9-bis[4-(2-acryloyloxy ethoxy) phenyl]fluorine; 2,2′-diacrylate-1,1′-binaphthalene; dicyclopentanyl diacrylate; 1,2-adamantanediol diacrylate; 2,4-diethylpentane-1,5-diol diacrylate; poly(ethylene glycol) diacrylate; 1,6-hexanediol (EO)2 diacrylate; 1,6-hexanediol (EO)5 diacrylate; and alkoxylated aliphatic diacrylate esters. Some non-limiting examples of suitable multifunctional acrylates to be included in the polymerizable material are: trimethylolpropane triacrylate; propoxylated trimethylolpropane triacrylate (e.g., propoxylated (3) trimethylolpropane triacrylate, propoxylated (6) trimethylolpropane triacrylate); trimethylolpropane ethoxylate triacrylate (e.g., n˜1.3,3,5); di(trimethylolpropane) tetraacrylate; propoxylated glyceryl triacrylate (e.g., propoxylated (3) glyceryl triacrylate); 1,3,5-adamantanetriol triacrylate; tris (2-hydroxy ethyl) isocyanurate triacrylate; pentaerythritol triacrylate; Trisphenol PA triacrylate; pentaerythritol tetracrylate; ethoxylated pentaerythritol tetracrylate; dipentaerythritol pentaacrylate; tripentaerythritol octaacrylate; trimethylolpropane(PO)n triacrylate (n is 1, 2, 3 . . . ); trimethylolpropane(EO)n triacrylate (n is 1, 2, 3 . . . ). Examples of the vinyl benzene type of monomers include vinylbenzene (styrene), divinylbenzene (DVB), trivinylbenzene (TVB), 3,3′-divinylbiphenyl, 3,4′,5-trivinylbiphenyl, 3,3′,5,5′-tetravinylbiphenyl, 1,2-bis(3-vinylphenyl)ethane, bis(4-vinylphenyl) ether, bis(3-vinylphenyl) ether. Some non-limiting examples of suitable multifunctional monomers to be included in the polymerizable material are: molecules containing both acrylate functional groups and vinyl groups directly connected to aromatic rings. For example, 3-vinyl benzyl acrylate, 2-(4-vinyl)-phenyl, 1,3-propane diacrylate, 3,5-bivinyl benzyl acrylate, and 5-vinyl, 1,3-xylene diacrylate. Some non-limiting examples of maleimides and bismaleimides to be included in the polymerizable material are: N-benzylmaleimide; N-cyclohexylmaleimide; N-phenylmaleimide; and bis(3-ethyl-5-methyl-4-maleimidophenyl)methane. Some non-limiting examples of suitable benzoxazines to be included in the polymerizable material are: 6,6′-Methylenebis[3,4-dihydro-3-phenyl-2H-1,3-benzoxazine; and 3,3′-(Methylenedi-4,1-phenylene)bis[3,4-dihydro-2H-1,3-benzoxazine.

Different fluid dispensers 122 may use different technologies to dispense the formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids. If the substrate 102 is brought to the dispensing station 103, and if the dispensing station 103 is a different location than the planarizing station 105, then the fluid dispensers 122 may be stationary. In another embodiment the fluid dispensers 122 may movable.

As shown in FIG. 1, the planarizing station 105 of the planarization system 100 may comprise a plate, e.g., a superstrate 108, having a working surface 112 facing and spaced apart from the substrate 102. The superstrate 108 may be formed from materials including, but not limited to, fused silica, quartz, silicon, organic polymers, siloxane polymers, borosilicate glass, fluorocarbon polymers, metal, hardened sapphire, and/or the like. In an embodiment the superstrate 108 is readily transparent to UV light radiation. The working surface 112 is generally of the same areal size as or slightly larger than the surface of the substrate 102. In the case of the shaping station being an imprinting station, the plate may be a template with a patterned surface.

The planarizing station 105 may further include a plate chuck, e.g., a superstrate chuck 118, and a planarization head 120. The superstrate 108 may be coupled to or retained by the superstrate chuck 118. The superstrate chuck 118 may be coupled to the planarization head 120. The planarization head 120 may be movably coupled to a bridge. The planarization head 120 may include one or more actuators such as voice coil motors, piezoelectric motors, linear motor, nut and screw motor, etc., which are configured to move the superstrate chuck 118 relative to the substrate 102 in at least the z-axis direction, and potentially other directions (e.g., x-, y-, θ-, Ψ-, and φ-axis). In operation, either the planarization head 120, the substrate positioning stage 106, or both vary a distance between the superstrate 108 and the substrate 102 to define a desired space (a bounded physical extent in three dimensions) that is filled with the formable material 124. For example, the planarization head 120 may be moved toward the substrate and may apply a force to the superstrate 108 such that the superstrate contacts and spreads droplets of the formable material 124 as further detailed herein. In the case the shaping station being an imprinting station, the plate chuck is a template chuck.

The planarizing station 105 may further comprise a camera 136 positioned to view the spread of formable material 124 as the superstrate 108 contacts the formable material 124 during the planarizing process. The camera 136 may include one or more of a CCD, a sensor array, a line camera, and a photodetector which are configured to gather light at a wavelength that shows a contrast between regions underneath the superstrate 108 and in contact with the formable material 124 and regions underneath the superstrate 108 but not in contact with the formable material 124. The camera 136 may be configured to provide images of the spread of formable material 124 underneath the superstrate 108, and/or the separation of the superstrate 108 from cured formable material 124. The camera 136 may also be configured to measure interference fringes, which change as the formable material 124 spreads between the gap between the working surface 112 and the substrate surface.

As noted above, the curing station 107 may be located at a different location than the planarizing station 105. In another embodiment the curing function may be implemented at the planarizing station 105 such that there is not a separate curing station. In yet another embodiment, all of the dispensing, planarizing, and curing may be implemented at a single location/station. In the case of there being a separate curing station 107, following the forming of the formable material film 144 at the planarizing station 105, the substrate 102 having a formable material film 144 and the superstrate 108 thereon, will travel to the curing station 107. The curing station 107 includes a radiation source 126 that directs actinic energy, for example, UV light radiation, along an exposure path 128. In an example embodiment the radiation source 126 comprises an array of light emitting diodes (LEDs) 127. The array of LEDs 127 may be configured such that the emitted light is distributed at 80% or greater uniformity across the substrate 102. The wavelength of the light emitted may be 300 to 400 nm. The substrate 102 and the superstrate 108, with the formable material film 144 in between, may be positioned in superimposition with the exposure path 128. The array of LEDs 127 transmits the actinic energy along the exposure path 128. In this manner, the actinic energy is uniformly applied to the formable material film 144. In the example embodiment where the curing occurs at the curing station 107, the system does not include (is free from) additional optical components (e.g., dichroic mirrors, beam combiners, prisms, lenses, mirrors, etc.). However, in an embodiment where the curing is implemented at the same location as the planarizing station, or in a case where all of the dispensing, planarizing, and curing occur at a single station, such optical components may be included at the common station to direct the energy to the formable material. The curing station 107 may further include a separate camera 137 for data collection and monitoring with respect to the curing process. In an embodiment where the curing features are implemented at the same location as the planarizing station, or in a case where all of the dispensing, planarizing, and curing occur at a single station, the camera 136 may be used to monitor curing.

The planarization system 100 may be regulated, controlled, and/or directed by one or more processors 140 (controller) in communication with one or more components and/or subsystems such as the substrate chuck 104, the substrate positioning stage 106, the positioning system the superstrate chuck 118, the fluid dispenser 122, the planarization head 120, the camera 136, the radiation source 126, and/or the camera 137. The processor 140 may operate based on instructions in a computer readable program stored in a non-transitory computer memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the method steps described herein may be executed by the processor 140.

### Planarization Method

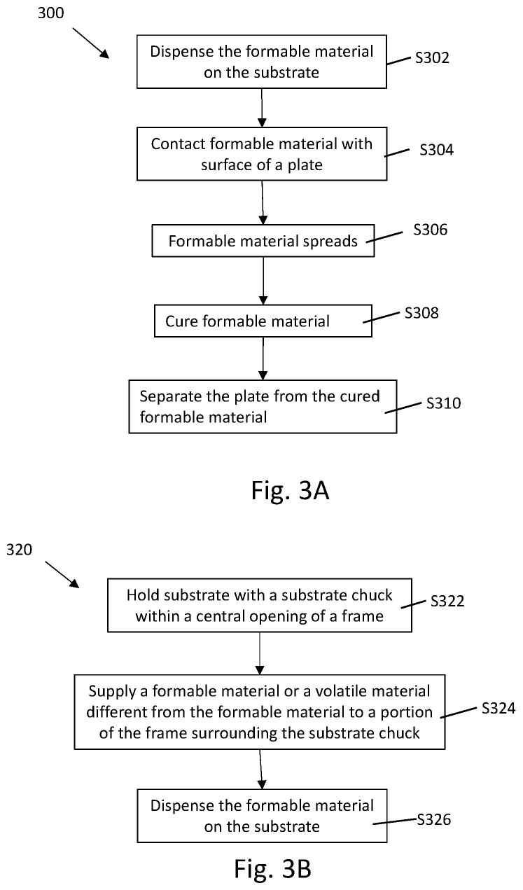

FIG. 3A shows a flow chart of a planarization method 300 in accordance with an example embodiment. The planarization method 300 may begin with step S302, where formable material 124 is dispensed onto the substrate 102 in the form of droplets. As discussed above, the substrate 102 surface has some topography which may be known based on previous processing operations or may be measured using a profilometer, AFM, SEM, or an optical surface profiler based on optical interference effect like Zygo NewView™ 8200. The local volume density of the deposited formable material 124 is varied depending on the substrate topography. The droplets of formable material 124 may be dispensed based on this information.

However, as part of performing the step S302, a method of inhibiting evaporation of the formable material S320 may be performed. The method of inhibiting evaporation S320 is shown in FIG. 3B. The method of inhibiting evaporation 320 may begin with step S322, where the substrate 102 is held by the substrate chuck 106 within the central opening 116 of the frame 110. The positioning system may be operated to pick up a substrate 102 from a substrate holder using a hand and to mount the substrate 102 on the substrate chuck 104 at the dispensing station 103. As discussed above, and shown in FIG. 2B, the substrate chuck 104 may be positioned within the central opening 116 of the frame 110 such that the body 114 of the frame 110 at least partially surrounds the substrate chuck 104. As also noted above, and shown in FIG. 2B, once the substrate 102 is held by the substrate chuck 104, the substrate 102 may also be positioned to be at least partially surrounded by the body 114 of the frame 110. FIG. 2B corresponds to the moment after step S322 is completed.

As shown in FIG. 3B, the method 320 may then proceed to step S324 where the formable material or a volatile material is supplied to a portion of the frame 110 (e.g., a portion of the body 114) surrounding the substrate chuck 104. However, in another example embodiment the step S324 may be performed after step S326, as discussed below.

In the case of the formable material being supplied to the frame 110, the formable material 124 is the same as the formable material discussed above. That is, in the case of the formable material being supplied to the body 114 of the frame 110, the formable material may be the same composition as the formable material composition that will be dispensed onto the substrate 102. In such an embodiment where the material supplied to the body 114 of the frame 110 is the formable material, the evaporation inhibition method 320 is performed in an absence of a curing light. As noted above, the formable material is a photocurable composition. Therefore, in the case of supplying the formable material to the body 114 of the frame 110, light is avoided to prevent curing of the formable material. For example, light having wavelengths in the range of 250 nm to 400 nm should be avoided in the case of supplying the formable material to the body 114 of the frame 110.

Supplying the formable material to the frame 110 is preferably chosen when the supplying occurs at a location other than the curing station (i.e., at the dispensing station) because is easier to avoid conditions that would cause the formable material to cure. As noted above, in some embodiments, the functionality of all three stations can be integrated into a single station. In such a case, where the curing occurs at the same location as the supplying of the material to the frame 110, the material supplied to the frame 110 is preferably not the same composition as the formable material. Rather, the material being supplied to the frame 110 is preferably a volatile material that is not photocurable. The volatile material not being photocurable is also referred herein as “non-reactive.” That is “non-reactive”, as used herein, means that the composition will not cure under the same conditions that will cause the formable material to cure. However, while it is best to avoid the formable material as the material supplied to the frame 110 in a case where the curing occurs at the same location, the reverse is not the case. That is, it is acceptable to use a non-reactive volatile material for the material supplied to the frame in a case where the curing occurs at another separate location. In other words, in a case where the curing occurs at another location the formable material, a non-reactive volatile material, or even a photocurable volatile material that is different from the formable material may be supplied to the frame.

In the case of the volatile material being supplied to the body 114 of the frame 110, the volatile material may be a liquid having a different composition than the formable material 124. As noted above, in one example embodiment, the formable material 124 may be a composition comprising: a photoinitiator; a surfactant; and a monomer. In that case, the volatile material may be the monomers that are also in the formable material 124, but excluding the photoinitiator.

With respect to the volatility, the volatile material may comprise those components of the formable material 124 that have a vapor pressure greater than a vapor pressure threshold. For example, the vapor pressure threshold may be 0.133 Pascals (0.001 mmHg). In an example embodiment, the formable material may comprise: a first photoinitiator with a vapor pressure that is less than vapor pressure threshold; and a first monomer and a first surfactant both of which have a vapor pressure higher than the threshold. In this case, the corresponding volatile material may be both the first monomer and the first surfactant, but excluding the photoinitiator. In another example, the formable material may comprise: a second surfactant with a vapor pressure that is less than vapor pressure threshold; and a second monomer with a vapor pressure higher than the threshold. In that case the volatile material comprises the second monomer, but not the first monomer.

In another example embodiment, the formable material 124 may be a solution having a solute that was solid prior to being in the solution and a solute that was liquid prior to being in the solution. In an example embodiment, the volatile material includes only the solute that was liquid prior to being in the solution and does not include the solute that was solid prior to being in solution.

The volatile material may be selected to satisfy each of the above-described aspects or any combination of the above-described aspects. That is, the volatile material may be selected to exclude a photoinitiator, to have the same monomers as the formable material, to have only components (e.g., monomers, surfactants, etc.) that have a vapor pressure greater than the vapor pressure threshold, and/or have only the solute that was liquid prior to being in solution.

By supplying the formable material or volatile material to the frame in an area surrounding the substrate, evaporation of the formable material is inhibited. In particular, evaporation of the formable material dispensed at the edges/perimeter of the substrate is inhibited. The evaporation of the formable material on the substrate, and particularly at the edges/perimeter of the substrate, is inhibited by supplying the formable material or the volatile material to the frame because the addition of the formable material or volatile material helps to saturate the vapor of the volatile components of the formable material environment in the area surrounding the formable material on the substrate. That is, when there is an open air environment surrounding the formable material, the formable material 124 will easily evaporate into the environment. However, when formable material or volatile material is supplied to the frame, the formable material or volatile material supplied to the frame evaporates into the surrounding area, approaching its saturation or equilibrium vapor pressure. Therefore, the formable material on the substrate will not easily evaporate because the surrounding environment is already at or near the saturation or equilibrium vapor pressure due to presence of the formable material or volatile material at the frame surrounding the substrate.

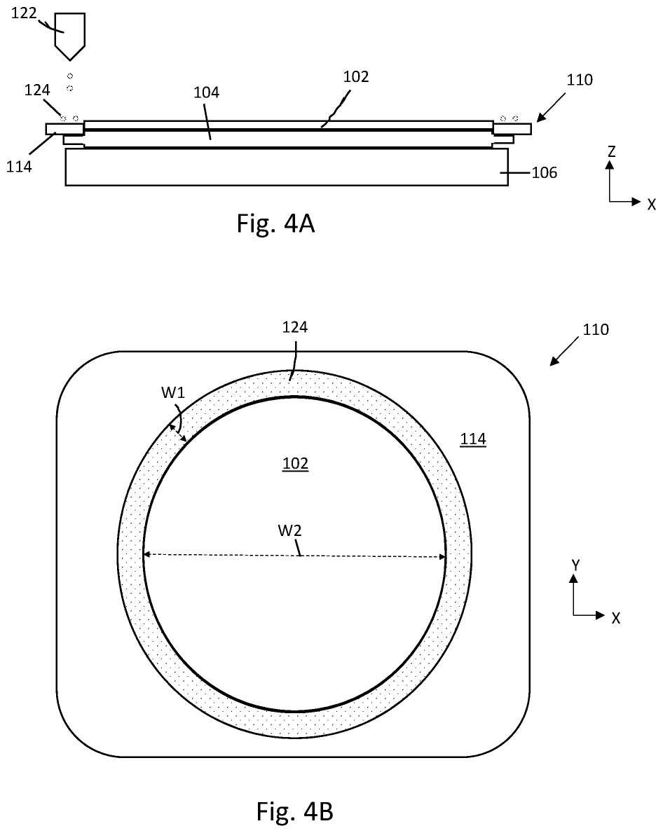

Several example embodiments regarding how to supply the formable material or the volatile material to the body 114 of the frame 110 are shown in FIGS. 4A through FIG. 10C. Each of the embodiments for supplying the formable material or the volatile material to the frame are also referred herein as a material supply system.

FIGS. 4A and 4B are directed to a first example embodiment where the step S324 of supplying the formable material or the volatile material to the body 114 of the frame 110 comprises dispensing the formable material 124 onto a surface of the body 114 of the frame 110 using the same dispenser 122 that is used to dispense the formable material 124 onto the substrate 102 FIG. 4A shows a schematic cross section view of the moment when the formable material 124 is supplied to a portion of a frame 110 surrounding a substrate chuck 104. As shown in FIG. 4A, the dispenser 122 is positioned above the body 114 of the frame 110 and then formable material 124 is dispensed onto the surface of the body 114. FIG. 4B shows a schematic plan view after the formable material 124 material has been supplied to the portion of the frame 110 surrounding the substrate chuck 104. As shown in FIG. 4B, the formable material 124 has been applied on the body 114 of the frame 110 via the dispenser 122 such that the formable material 124 is circumferentially disposed around the perimeter of the substrate 102. The formable material 124 dispensed on the frame 110 may begin at the inner edge of the body 114 that defines the central opening 116 and extend radially away from the opening 116. A ratio of the radial width W1 of the dispensed formable material 124 on the frame 110 to the diameter W2 of the substrate chuck 104 (or the substrate 102) is 1:15 to 1:50. The formable material 124 may cover 10% to 75% of the surface area of the frame 110

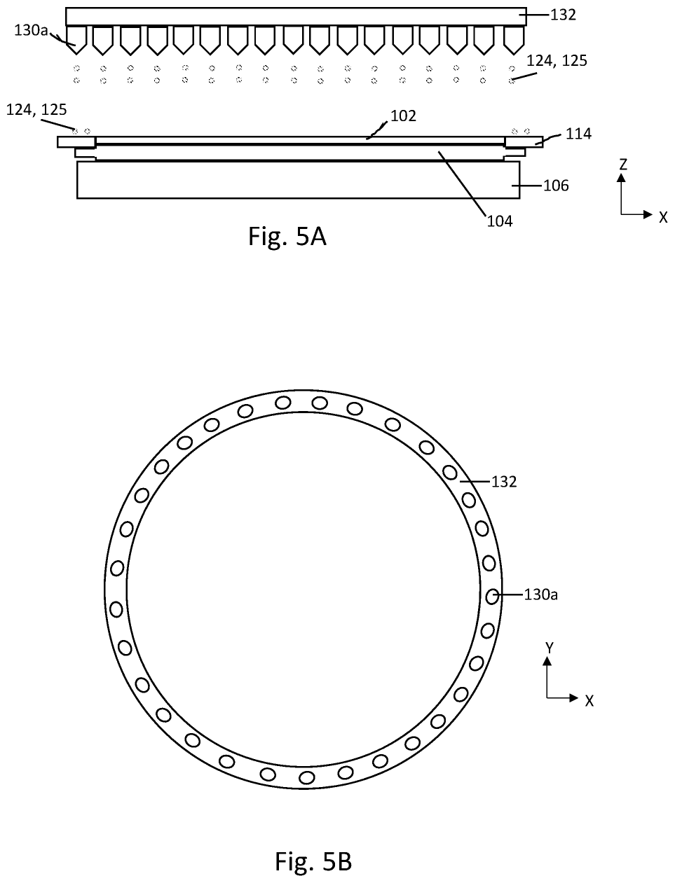

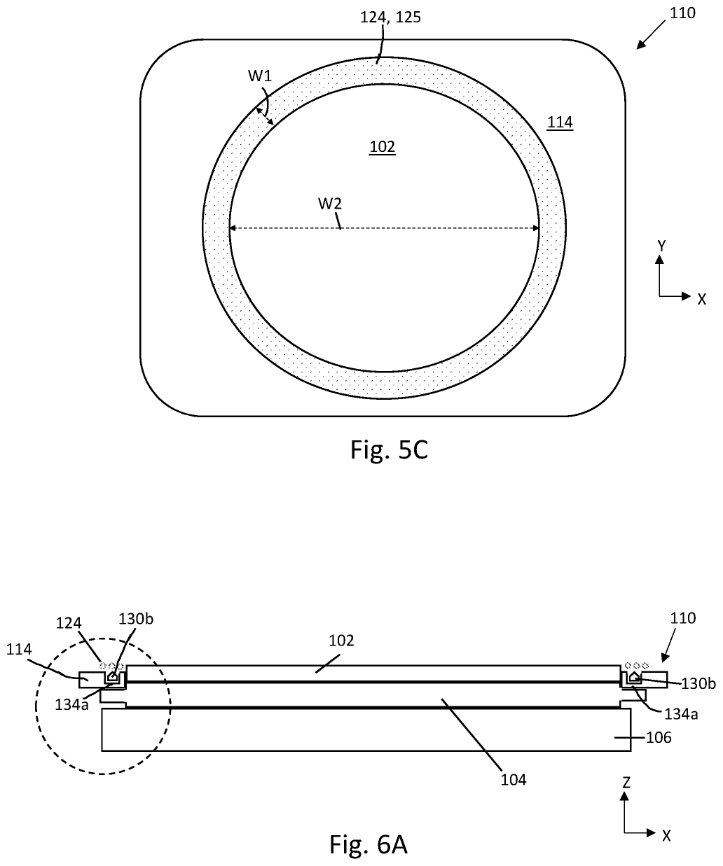

FIGS. 5A to 5C are directed to a second example embodiment where the step S324 of supplying the formable material 124 or the volatile material 125 to the body 114 of the frame 110 comprises dispensing the formable material 124 or the volatile material 125 onto a surface of the body 114 of the frame using a set of nozzles 130a that is separate from the dispenser 122. FIG. 5A shows a schematic cross section view of the frame 110, substrate 102, and substrate chuck 104 at the moment when the formable material 124 or the volatile material 125 is supplied to a portion of a frame 110 surrounding a substrate chuck 104. FIG. 5B shows a schematic bottom view of the set of nozzles 130a.

As shown in FIG. 5A, the set of nozzles 130a is positioned above the body 114 of the frame 110 and then formable material 124 or volatile material 125 is dispensed onto the surface of the body 114 of the frame 110. As shown in FIG. 5B, the set of nozzles 130a may be mounted to a support member 132. The support member 132 may have a ring shape may carry the set of nozzles 130a. The support member 132 carrying the set of nozzles 130a may be positionable above the body 114 of the frame 110. FIG. 5C shows a schematic plan view after the formable material 124 or volatile material 125 has been supplied to the portion of the frame 110 surrounding the substrate chuck 104. As shown in FIG. 5C, the formable material 124 or the volatile material 125 has been applied on the body 114 of the frame 110 via the set of nozzles 130a such that the formable material 124 or the volatile material 125 is circumferentially disposed around the perimeter of the substrate 102. The formable material 124 or the volatile material 125 dispensed on the frame 110 may begin at the inner edge of the body 114 that defines the central opening 116 and extend radially away from the opening 116. A ratio of the radial width W1 of the dispensed formable material 124 or the volatile material 125 on the frame 110 to the diameter W2 of the substrate chuck 104 (or the substrate 102) is the same as provided above. The formable material 124 or the volatile material 125 may cover the same amount of the surface area of the frame 110 as provided above.

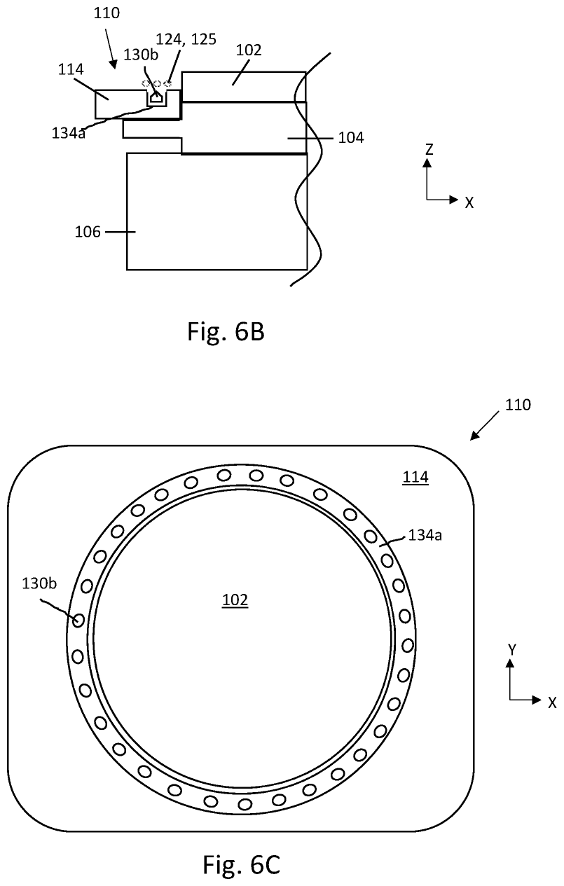

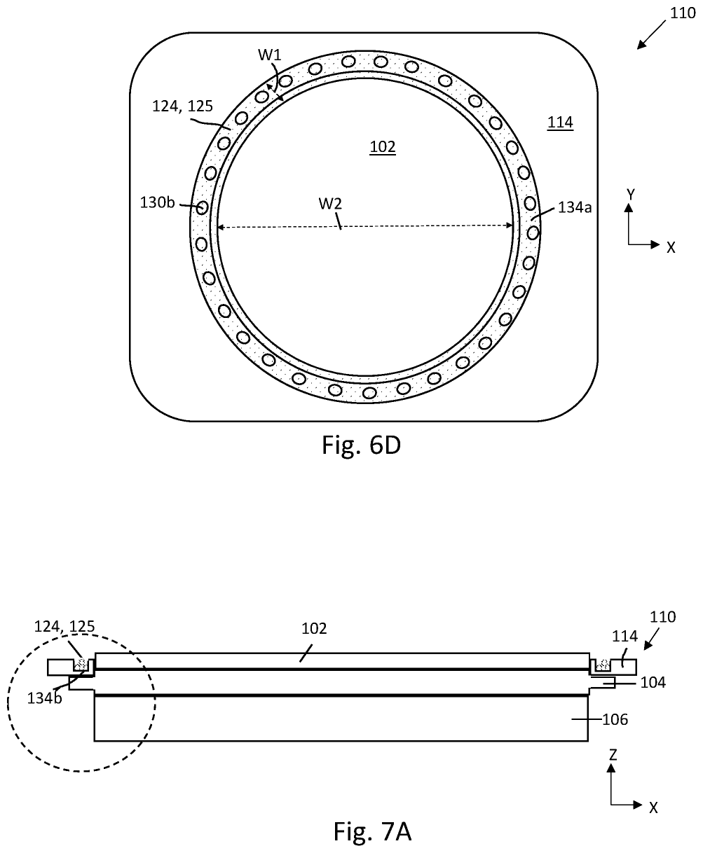

FIGS. 6A to 6D are directed to a third example embodiment where the step S324 of supplying the formable material 124 or the volatile material 125 to the body 114 of the frame 110 comprises dispensing the formable material 124 or the volatile material 125 onto a surface of the body 114 of the frame using a set of nozzles 130b that is separate from the dispenser 122. FIG. 6A shows a schematic cross section view of the frame 110, substrate 102, and substrate chuck 104 at the moment when the formable material 124 or the volatile material 125 is supplied to a portion of a frame 110 surrounding a substrate chuck 104. FIG. 6B shows an enlarged portion of FIG. 6A. FIG. 6C shows a schematic plan view of the frame 110, substrate 102, and substrate chuck 104 at a moment before the formable material 124 or volatile material 125 has been supplied to the portion of the frame 110 surrounding the substrate chuck 104. FIG. 6D shows a schematic plan view of the frame 110, substrate 102, and substrate chuck 104 at a moment after the formable material 124 or volatile material 125 has been supplied to the portion of the frame 110 surrounding the substrate chuck 104.

As shown in FIGS. 6A and 6B, the set of nozzles 130b is positioned within a channel 134a formed in the body 114 of the frame 110 and then formable material 124 or volatile material 125 is dispensed onto the surface of the body 114 of the frame 110 using the set of nozzles 130b. As shown in FIG. 6C, the channel 134a may be a circular channel surrounding the outer edge of the substrate chuck 104 and/or substrate 102. As also shown in FIG. 6C, the set of nozzles 130b may be provided throughout the channel 134a. Thus, the set of nozzles 130b also surround the outer edge of the substrate chuck 104 and/or substrate chuck 102. As shown in FIG. 6D, the formable material 124 or the volatile material 125 has been applied on the body 114 of the frame 110 via the set of nozzles 130b such that the formable material 124 or the volatile material 125 is circumferentially disposed around the perimeter of the substrate chuck 104 and substrate 102. The formable material 124 or the volatile material 125 dispensed on the frame 110 may begin at the inner edge of the body 114 that defines the central opening 116 and extend radially away from the opening 116. A ratio of the radial width W1 of the dispensed formable material 124 or the volatile material 125 on the frame 110 to the diameter W2 of the substrate chuck 104 (or the substrate 102) is the same as provided above. The formable material 124 or the volatile material 125 may cover the same amount of the surface area of the frame 110 as provided above. The set of nozzles 130b may be in communication with a source of the formable material 124 or the volatile material 125.

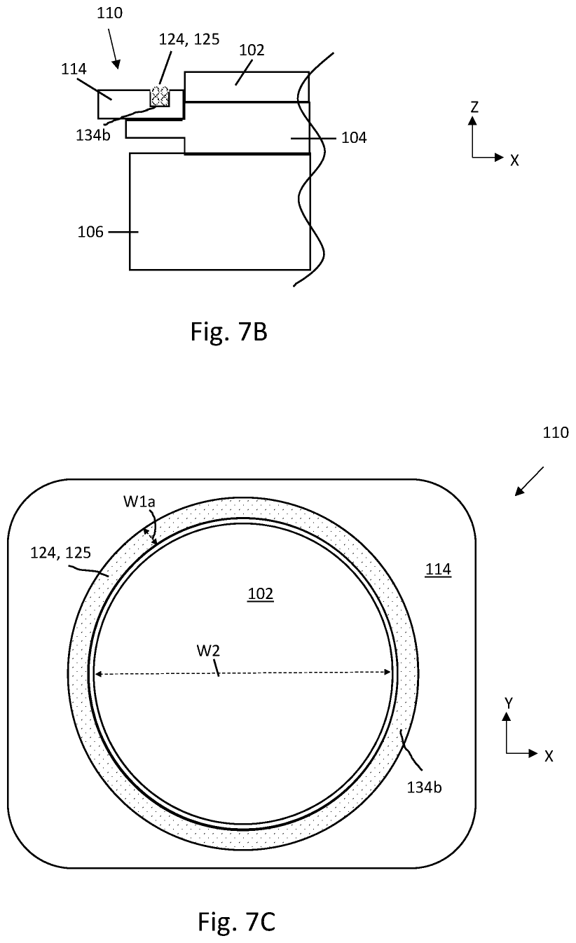

FIGS. 7A to 7C are directed to a fourth example embodiment where the step S324 of supplying the formable material 124 or the volatile material 125 to the body 114 of the frame 110 comprises providing the formable material 124 or the volatile material 125 into a channel 134b formed in the body 114 of the frame 110. FIG. 7A shows a schematic cross section view of the frame 110, substrate 102, and substrate chuck 104 after the formable material 124 or the volatile material 125 has been supplied to the channel 134b formed in a portion of a frame 110 surrounding a substrate chuck 104. FIG. 7B shows an enlarged portion of FIG. 7A. FIG. 7C shows a schematic plan view of the frame 110, substrate 102, and substrate chuck 104 after the formable material 124 or the volatile material 125 has been supplied to the channel 134b formed in a portion of a frame 110 surrounding a substrate chuck 104.

As shown in FIGS. 7A and 7B, the channel 134b is formed in the body 114 of the frame 110 and then formable material 124 or volatile material 125 is provided in the channel 134b. The formable material 124 or the volatile material 125 may be provided into the channel with a dispenser (such as the dispenser 122 or the set of nozzles 130a). As shown in FIG. 7C, the channel 134b may be a circular channel surrounding the outer edge of the substrate chuck 104 and/or substrate 102. As also shown in FIG. 7C, the formable material 124 or volatile material 125 may be provided throughout the channel 134b. Thus, channel 134b with formable material 124 or volatile material 125 surrounds the outer edge of the substrate chuck 104 and/or substrate chuck 102. As shown in FIG. 7C, the formable material 124 or the volatile material 125 has been applied on the body 114 of the frame 110 via channel 134b such that the formable material 124 or the volatile material 125 is circumferentially disposed around the perimeter of the substrate chuck 104 and substrate 102. Because the formable material 124 or the volatile material 125 is confined within the channel 134b and not on the surface of the body 114, a ratio of the radial width W1a of the formable material 124 or the volatile material 125 in the frame 110 to the diameter W2 of the substrate chuck 104 (or the substrate 102) is slightly smaller than provided above example embodiments. For example, the ratio of the radial width W1a of the formable material 124 or the volatile material 125 in the channel 134b to the diameter W2 of the substrate chuck 104 (or the substrate 102) is 1:20 to 1:55. Similarly, the formable material 124 or the volatile material 125 may cover slightly less of the surface area of the frame 110 as compared to the above example embodiments. For example, the formable material 124 or the volatile material 125 may cover 8% to 70% of the surface area of the frame 110.

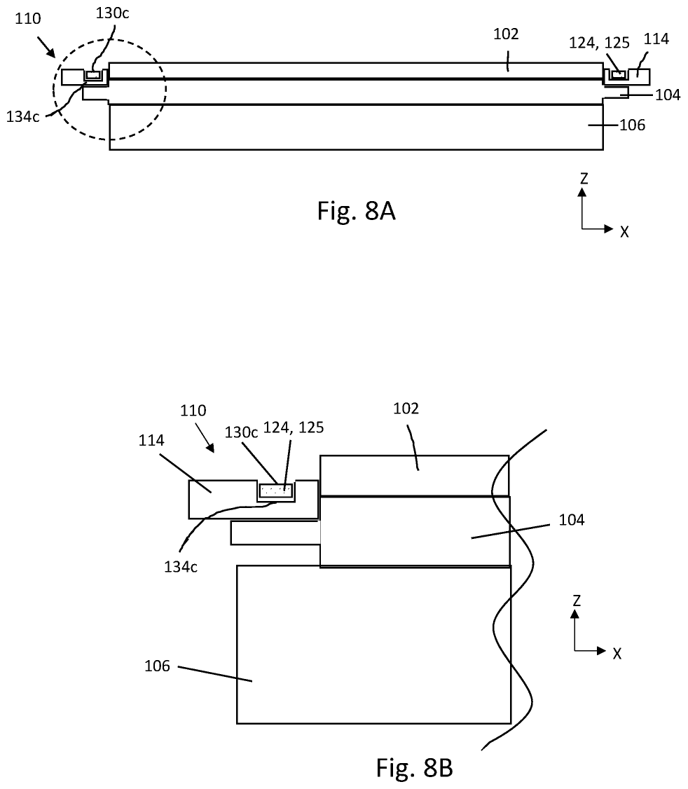

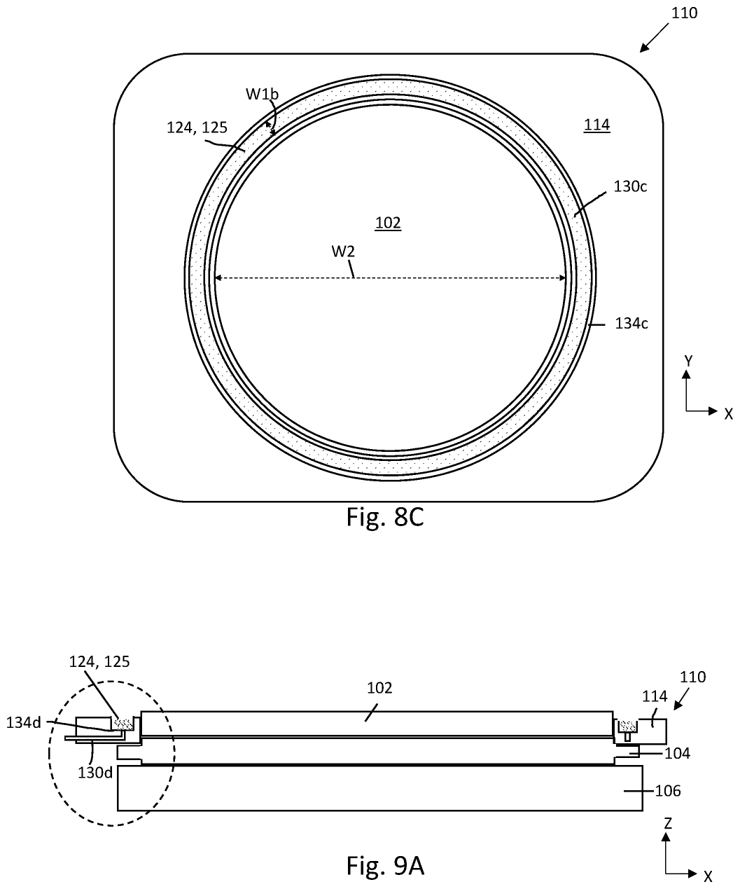

FIGS. 8A to 8C are directed to a fifth example embodiment where the step S324 of supplying the formable material 124 or the volatile material 125 to the body 114 of the frame 110 comprises providing a porous pad 130c, having the formable material 124 or the volatile material 125 held therein, into a channel 134c formed in the body 114 of the frame 110. FIG. 8A shows a schematic cross section view of the frame 110, substrate 102, and substrate chuck 104 after the porous pad 130c having the formable material 124 or the volatile material 125 has been placed in the channel 134c. FIG. 8B shows an enlarged portion of FIG. 8A. FIG. 8C shows a schematic plan view of the frame 110, substrate 102, and substrate chuck 104 after the porous pad 130c having the formable material 124 or the volatile material 125 has been supplied to the channel 134c.

As shown in FIGS. 8A and 8B, the channel 134c is formed in the body 114 of the frame 110 and then porous pad 130c is provided in the channel 134c. In an embodiment, the porous pad 130c may have been already soaked with the formable material 124 or the volatile material 125 prior to inserting the porous pad 130c into the channel 134c. In another embodiment, the porous pad 130c may be first placed into the channel 134c without the formable material 124 and without the volatile material 125. In the case of providing the porous pad 130c in the channel 134c without prior application of formable material or volatile material, the formable material 124 or the volatile material 125 may be provided to the porous pad 130c with a dispenser (such as the dispenser 122 or the set of nozzles 130a). As shown in FIG. 8C, the channel 134c may be a circular channel surrounding the outer edge of the substrate chuck 104 and/or substrate 102.

As also shown in FIG. 8C, the porous pad 130c may be provided throughout the channel 134c. Thus, channel 134c with the porous pad 130c, having the formable material 124 or volatile material 125, surrounds the outer edge of the substrate chuck 104 and/or substrate chuck 102. As shown in FIG. 8C, the formable material 124 or the volatile material 125 has been supplied to the body 114 of the frame 110 via the porous pad 130c in the channel 134c such that the formable material 124 or the volatile material 125 is circumferentially disposed around the perimeter of the substrate chuck 104 and substrate 102. Because the formable material 124 or the volatile material 125 is confined within the porous pad 130c, which itself is confined to the channel 134c, and not on the surface of the body 114, a ratio of the radial width W1b of the formable material 124 or the volatile material 125 in the frame 110 to the diameter W2 of the substrate chuck 104 (or the substrate 102) is slightly smaller than provided above example embodiments. For example, the ratio of the radial width W1b of the formable material 124 or the volatile material 125 in the channel 134c to the diameter W2 of the substrate chuck 104 (or the substrate 102) is 1:30 to 1:60. Similarly, the formable material 124 or the volatile material 125 may cover slightly less of the surface area of the frame 110 as compared to the above example embodiments. For example, the formable material 124 or the volatile material may cover 5% to 65% of the surface area of the frame 110. Alternatively, the relative physical dimensions can be modified so that the ratio of the radial width of the formable material or the volatile material in the channel to the diameter of the substrate chuck is the same as any of the above embodiments. Similarly, the relative physical dimensions can be modified so that formable material or the volatile material may cover the same percentage of the surface area of the frame as the in the above embodiments.

The porous pad may be sintered or perforated, for example. The porous pad may have a volume fraction of at least 0.64. The pad is preferably open cell so that the voids create a network that can exchange with each other and the external environment. The porous pad may have void size of 0.03 microns to 100 microns. The porous pad may be made of metal such as stainless steel, titanium, nickel, ceramic such as alumina or silicon carbide, or a polymer material such as polyether ether ketone (PEEK), polyoxymethylene (also known as acetal), polytetrafluoroethylene (PTFE), or perfluoroalkoxy alkane (PFA). The sintered material may be coated with a material such as parylene to act as a barrier for metal ion transport or alter the wettability of the material. The porous pad may have a relatively large surface area while being relatively thin. The porous pad may extend across substantially the entire inner width of the channel 134c. Thus, the porous pad may have a have an outer diameter that is just smaller than the inner diameter of the channel 134c. That is, the outer diameter of the porous pad may be as large as possible while still fitting within channel 134c.

In an example embodiment, the porous pad can be replaced with a fresh porous pad having the formable material or the volatile material after a predetermined threshold has passed. Over time the volatile components will eventually evaporate and dissipate to the point that previously placed porous pad will no longer sufficiently inhibit evaporation of the formable material on the substrate. Therefore, by replacing the porous pad with a new porous pad that contains an optimal amount of formable material or volatile material, the evaporation of the formable material on the substrate can continue to be inhibited. The predetermined threshold can be based on a predetermined amount of time or based on a predetermined number of substrates that have been proceed. The predetermined threshold (e.g., the predetermined amount of time or predetermined number of substrates processed) can be determined using modelling or experimentally. For example, for a particular fabrication, including the particular materials used and particular compositions, the amount of evaporation of the formable material or volatile material can be modeled over time. Alternatively (or additionally), actual fabrications can be run and the amount of evaporation can be measured over time.

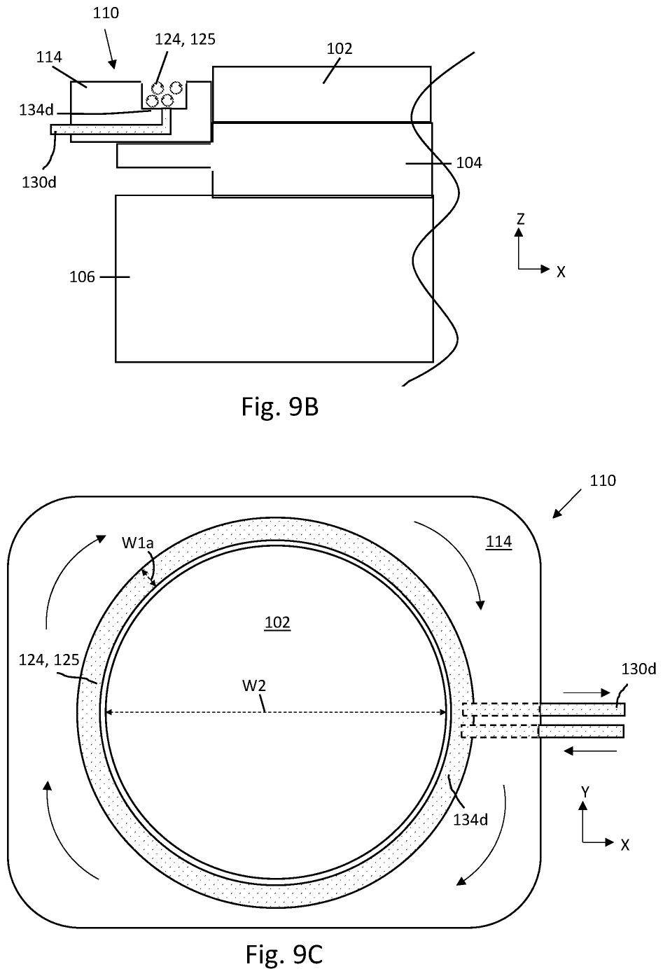

FIGS. 9A to 9C are directed to a sixth example embodiment where the step S324 of supplying the formable material 124 or the volatile material 125 to the body 114 of the frame 110 comprises providing the formable material 124 or the volatile material 125 into a channel 134d formed in the body 114 of the frame 110. The sixth embodiment shown in FIGS. 9A to 9C is similar to the fourth embodiment shown in FIGS. 7A to 7C, except that a recirculating line 130d is included to circulate the formable material 124 or the volatile material 125 throughout the channel 134d. FIG. 9A shows a schematic cross section view of the frame 110, substrate 102, and substrate chuck 104 after the formable material 124 or the volatile material 125 has been supplied to the channel 134d formed in a portion of a frame 110 surrounding a substrate chuck 104. FIG. 9B shows an enlarged portion of FIG. 9A. FIG. 9C shows a schematic plan view of the frame 110, substrate 102, and substrate chuck 104 as the formable material 124 or the volatile material 125 is circulated through the channel 134d.

As shown in FIGS. 9A and 9B, the channel 134d is formed in the body 114 of the frame 110 and then formable material 124 or volatile material 125 is provided in the channel 134d. The formable material 124 or the volatile material 125 may be provided into the channel via a recirculating line 130d. In another example embodiment, a gravity feed may be used in place of a recirculating line. As shown in FIG. 9C, the channel 134d may be a circular channel surrounding the outer edge of the substrate chuck 104 and/or substrate 102. As also shown in FIG. 9D, the formable material 124 or volatile material 125 may be provided throughout the channel 134d. Thus, channel 134d with formable material 124 or volatile material 125 surrounds the outer edge of the substrate chuck 104 and/or substrate chuck 102. As shown in FIG. 9D, the formable material 124 or the volatile material 125 has been applied on the body 114 of the frame 110 via channel 134d such that the formable material 124 or the volatile material 125 is circumferentially disposed around the perimeter of the substrate chuck 104 and substrate 102. As shown in FIG. 9D, the formable material 124 or volatile material 125 may be circulated throughout the channel 134d via the recirculating line 130d. The arrows in FIG. 9D indicate the direction of flow of the formable material 124 or volatile material 125 in the illustrated example embodiment (e.g., clockwise from the plan view). However, the reverse direction may also be implemented. The flow may be controlled by a pump for example.

The formable material 124 or the volatile material 125 is confined within the channel 134d and not on the surface of the body 114 in the same manner as in the fourth example embodiment. Thus, the ratio of the radial width W1a of the formable material 124 or the volatile material 125 in the frame 110 to the diameter W2 of the substrate chuck 104 (or the substrate 102) the same as in the fourth example embodiment. Similarly, formable material 124 may cover the same surface area of the frame 110 as in the fourth example embodiment.

FIGS. 10A to 10C are directed to a seventh example embodiment where the step S324 of supplying the formable material 124 or the volatile material 125 to the body 114 of the frame 110 comprises providing a porous pad 130e, having the formable material 124 or the volatile material 125 therein, into a channel 134e formed in the body 114 of the frame 110, similar to the fifth example embodiment. However, the example embodiment shown in FIGS. 10A to 10C additionally includes an evaporation accelerator 131 as compared to fifth example embodiment. FIG. 10A shows a schematic cross section view of the frame 110, substrate 102, and substrate chuck 104 after the porous pad 130e having the formable material 124 or the volatile material 125 has been placed in the channel 134e on top of the evaporation accelerator 131. FIG. 1013 shows an enlarged portion of FIG. 10A. FIG. 10C shows a schematic plan view of the frame 110, substrate 102, and substrate chuck 104 after the porous pad 130e having the formable material 124 or the volatile material 125 has been supplied to the channel 134e on top of the evaporation accelerator 131.

As shown in FIGS. 10A and 10B, the channel 134e is formed in the body 114 of the frame 110 and then porous pad 130e is provided in the channel 134e on top of the evaporation accelerator 131. The evaporation accelerator 131 may be a heating pad or a nebulizing transducer, for example. In an embodiment, the porous pad 130e may have been preemptively soaked with the formable material 124 or the volatile material 125 prior inserting the porous pad 130e into the channel 134e on top of the evaporation accelerator 131. In another embodiment, the porous pad 130e may be first placed into the channel 134e on top of the evaporation accelerator 131, but without the formable material 124 and without the volatile material 125. In the case of providing the porous pad 130e in the channel 134e without the formable material 124 or the volatile material 125, the formable material 124 or the volatile material 125 may be provided to the porous pad 130e with a dispenser (such as the dispenser 122 or the set of nozzles 130a). As shown in FIG. 10C, the channel 134e may be a circular channel surrounding the outer edge of the substrate chuck 104 and/or substrate 102.

As also shown in FIG. 10C, the porous pad 130e may be provided throughout the channel 134e. The porous pad 130e may be the same as the porous pad 130e discussed as above with respect to the fifth example embodiment. Similarly, the evaporation accelerator 131 may be provided through the channel 134e underneath the porous pad 130e. The outer diameter of the evaporation accelerator 131 may be the same size as the porous pad 130e relative to the inner diameter of the channel 134e. Thus, channel 134e with the porous pad 130e, having the formable material 124 or volatile material 125, as well as the evaporation accelerator 131, surrounds the outer edge of the substrate chuck 104 and/or substrate chuck 102. As shown in FIG. 10C, the formable material 124 or the volatile material 125 has been supplied to the body 114 of the frame 110 via the porous pad 130e in the channel 134e such that the formable material 124 or the volatile material 125 is circumferentially disposed around the perimeter of the substrate chuck 104 and substrate 102. A ratio of the radial width W1b of the formable material 124 or the volatile material 125 in the frame 110 to the diameter W2 of the substrate chuck 104 (or the substrate 102) is the same as discussed above with respect to the fifth example embodiment of FIGS. 8A to 8C. Similarly, the formable material 124 or the volatile material 125 may cover the same relative surface area of the frame 110 as discussed above with respect to the fifth embodiment of FIGS. 8A to 8C.

As noted above, each of the seven example embodiments discussed above are examples of performing the step S324 to supply the formable material or the volatile material to a portion of the frame surrounding the substrate chuck. In the example embodiments, the step S324 is performed prior to a step S326 of dispensing of the formable material on the substrate. Furthermore, as noted above, in the example system shown in FIG. 1, the dispensing may occur at a separate dispensing station 103. However, in other embodiments, the step S326 of dispensing the formable material onto the substrate may be performed prior to the step S324. Furthermore, in a case of supplying the formable material or volatile material to the frame after the dispensing, the step of supplying the formable material or the volatile material to the frame may be performed at the planarization station 105 and/or the curing station 107 in addition to or instead of performing it at the dispensing station 103. That is, the same approach to inhibiting evaporation may be performed at every station along the process, as every station includes a frame. Furthermore, as also noted above, in some example embodiments, one or more or all functions of dispensing, planarizing, and curing may be integrated into the same location. In that case, the step of supplying the formable material or the volatile material to the frame may be performed prior to the dispensing and/or at any point along the process all the way through curing. In any of the example embodiments, whenever there is potential exposure to curing light, e.g., at the curing station or in a case where the curing functionality is integrated with the dispensing and/or planarizing, the material supplied to the frame is the non-reactive volatile material and not the formable material. In any of the embodiments where there will not be a curing light applied, either the formable material or the volatile material may be supplied to the frame, but in a case where curing will be performed the formable material is not supplied. More particularly, in the case where curing is performed at the same location in which the volatile material is supplied to the frame, the volatile material is non-reactive.

An example embodiment of the step S326 of dispensing the formable material 124 onto the substrate 102 is shown in FIGS. 11A and 11B. FIG. 11A shows a schematic cross section view of the dispenser 122 beginning to dispense the formable material 124 onto the substrate 102. In the example embodiment of FIG. 11A, the formable material 124 or volatile material 125 has already been supplied to the frame 110. FIG. 11B shows a schematic cross section view after the dispenser 122 has completed dispensing the formable material 124 onto the substrate 102. As shown in FIG. 11B, in the case where step S326 is performed after step S324, after completing step S326 the substrate 102 is covered with the formable material 124 and the formable material 124 or the volatile material 125 has been supplied to the frame 110. While FIGS. 11A and 11B correspond to the embodiment where the formable material 124 or the volatile material 125 is supplies directly onto a surface of the frame 110, the step S326 of dispensing the formable material is applicable to any the methods of the supplying the formable material 125 or the volatile material 125 to the frame 110.

Returning to the method 300, the after the dispensing step S302, including performing the method of inhibiting evaporation 320, the method 300 may proceed to step S304 where the dispensed formable material is contacted with the surface of the plate, i.e., the superstrate. FIGS. 11A to 11C show schematic cross sections specifically regarding step S306 to step S302, i.e., from contacting the formable material at the planarizing station 105 through separating the superstrate from the cured layer.

FIG. 11A shows a schematic cross section at the planarizing station 105 at the moment just before the superstrate 108 comes into the contact with the formable material 124 on the substrate 102. The planarization head 120 may be moved toward the substrate 102 and apply a force to the superstrate 108 such that the superstrate 108 contacts (S304) and spreads (S306) droplets of the formable material 124.

FIG. 11B illustrates a post-contact step after the superstrate 108 has been brought into full contact with the formable material 124. As the superstrate 108 contacts the formable material 124, the droplets merge to form a formable material film 144 that fills the space between the superstrate 108 and the substrate 102. Preferably, the filling process happens in a uniform manner without any air or gas bubbles being trapped between the superstrate 108 and the substrate 102 in order to minimize non-fill defects. At the moment shown in the FIG. 11B, the steps S304 and S306 have been completed.

The planarization method 310 may then proceed to step S308, where the spread formable material is cured. The curing may occur at a separate curing station 107 as illustrated in FIG. 1 or may be cured at the same location as the planarizing station 105 in another embodiment. When the curing occurs at the curing station 107, the superstrate 108 is released from the superstrate chuck 118 while the superstrate 108 is still in contact with the formable material film 144. This action of releasing the superstrate 108 from the superstrate chuck 118 leaves the superstrate 108/the film 144/the substrate 102 free from the planarization head 120. The releasing of the superstrate 108 from the superstrate chuck 118 may also be referred to as dechucking. After reaching the curing station 107, the formed film layer 144 is cured. The polymerization process or curing of the formable material 124 may be initiated with actinic radiation (e.g., UV light radiation). For example, radiation source 126 provides the actinic radiation causing formable material film 144 to cure, solidify, and/or cross-link, defining a cured layer 146 on the substrate 102. More particularly, as shown in FIG. 1, the UV light radiation is emitted from the array of LEDs 127 that are directed toward the film 144. Because the superstrate 108 is configured to be transparent with respect to the UV light radiation emitted from the array of LEDs 127, the UV light radiation passes through the superstrate 108 and acts upon the formable material film 144 to cure the formable material film 144 resulting in the cured layer 146. When the curing process is complete, the formable material film 144 has become a cured layer 146. In an embodiment where the curing occurs at the same location as the planarizing station 105, the light source may be provided above planarization head 120 and the light may be directed through the superstrate chuck 118 and the superstrate 108 to reach the film 144.

The planarization method 310 may then proceed to step S310, where the superstrate 108 is separated from the cured layer 146. In the case when the curing was performed at the separate curing station 107, the superstrate 108/the cured layer 146/the substrate 102 may be brought back to the planarizing station 105. To remove the superstrate 108 from the cured layer 146 the superstrate chuck 118 may be coupled once again to the superstrate 108 (i.e., rechucking the superstrate 108) via operation of the planarization head 120, while the superstrate 108 is still in contact with the cured layer 146. In the case that the curing occurs at the same location of the planarizing station 105, the superstrate 108 remains coupled with the superstrate chuck 118 and there is no rechucking step. Once the superstrate 108 is coupled with the superstrate chuck 118, the superstrate chuck 118 may begin to lift upwardly away from the substrate 102, via operation of the planarization head 120. Because the superstrate 108 is coupled with superstrate chuck 118, the lifting force will cause the superstrate 108 to separate from the cured layer 146. The separating force may be applied through several different methods. For example, the separating force may be applied by a pin pushing up on the superstrate 108, by a vacuum pulling up on the upper surface 141 of the superstrate 108, and/or by applying a high pressure jet of air at the intersection of the cured layer 146 and the superstrate 108.

FIG. 11C shows a schematic cross section of the substrate 102 after the superstrate 108 has been removed from the cured layer 146, i.e., after the completion of step S310. That is, FIG. 11C shows the completed cured planarized layer 146 on the substrate 102. The substrate 102 and the cured layer 146 may then be subjected to additional known steps and processes for device (article) fabrication, including, for example, patterning, curing, oxidation, layer formation, deposition, doping, planarization, etching, formable material removal, dicing, bonding, and packaging, and the like. The substrate 102 may be processed to produce a plurality of articles (devices). These additional steps may be performed by moving the substrate 102 having the exposed cured layer 146 to a distinct location. Once the substrate 102, having the exposed cured layer 146, is moved, the planarizing station 105 is ready to receive a new substrate with formable material and repeat the above process.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method of inhibiting evaporation of a formable material on a substrate, the method comprising:
holding the substrate with a substrate chuck, the substrate chuck being positioned within a central opening of a frame such that the frame surrounds at least a portion of the substrate chuck;
supplying the formable material or a volatile material different from the formable material to a portion of the frame surrounding the substrate chuck; and
dispensing the formable material on the substrate.

2. The method of claim 1, wherein the supplying of the formable material or the volatile material is performed prior to the dispensing of the formable material.

3. The method of claim 1, wherein the dispensing of the formable material is performed prior to the supplying of the formable material or the volatile material.

4. The method of claim 1, comprising supplying the formable material to the portion of the frame surrounding the substrate chuck.

5. The method of claim 4,
wherein the dispensing of the formable material on the substrate comprises dispensing the formable material using a dispenser, and
wherein the supplying of the formable material to a portion of the frame surrounding the substrate chuck comprises dispensing the formable material onto a surface of the frame using the dispenser.

6. The method of claim 4, wherein the formable material is photocurable.

7. The method of claim 1, comprising supplying the volatile material to the portion of the frame surrounding the substrate chuck.

8. The method of claim 7, wherein the volatile material is not photocurable.

9. The method of claim 7, wherein the volatile material does not include a photoinitiator.

10. The method of claim 7,
wherein the formable material comprises volatile components, and
wherein the volatile material comprises the same volatile components as the formable material.

11. The method of claim 1, wherein the supplying of the formable material or the volatile material to the portion of the frame surrounding the substrate chuck comprises dispensing the formable material or the volatile material onto a surface of the frame.

12. The method of claim 1, wherein the supplying of the formable material or the volatile material to the portion of the frame surrounding the substrate chuck comprises dispensing the formable material or the volatile material into a channel formed in the frame.

13. The method of claim 1, wherein the supplying of the formable material or the volatile material to the portion of the frame surrounding the substrate chuck comprises dispensing the formable material or the volatile material onto a surface of the frame using a set of nozzles.

14. The method of claim 13, wherein the set of nozzles is disposed in a channel formed in the frame.

15. The method of claim 1, wherein the supplying of the formable material or the volatile material to the portion of the frame surrounding the substrate chuck comprises providing a porous pad containing the formable material or the volatile material into a channel formed in the frame.

16. The method of claim 15, wherein the supplying of the formable material or the volatile material to the portion of the frame surrounding the substrate chuck further comprises, after passing a predetermined threshold, replacing the porous pad with another porous pad containing the formable material or the volatile material.

17. The method of claim 15, wherein the supplying of the formable material or the volatile material to the portion of the frame surrounding the substrate chuck further comprises accelerating evaporation of the formable material or the volatile material using an evaporation accelerator disposed underneath the porous pad.

18. The method of claim 1, wherein the supplying of the formable material or the volatile material to the portion of the frame surrounding the substrate chuck comprises circulating the formable material or the volatile material the through a channel formed in the frame.

19. A system for inhibiting evaporation of a formable material on a substrate, the system comprising:
a frame defining a central opening;
a substrate chuck configured to hold the substrate, the substrate chuck being positioned within the central opening of the frame such that the frame surrounds at least a portion of the substrate chuck; and
a material supply system configured to supply the formable material or a volatile material different from the formable material to a portion of the frame surrounding the substrate chuck.

20. A method of manufacturing an article, comprising:
holding a substrate with a substrate chuck, the substrate chuck being positioned within a central opening of a frame such that the frame surrounds at least a portion of the substrate chuck;
supplying a formable material or a volatile material different from the formable material to a portion of the frame surrounding the substrate chuck;
dispensing formable material onto the substrate;
forming a pattern or a layer of the dispensed formable material on the substrate;
curing the formed pattern or layer; and
processing the cured pattern or layer to make the article.
